(19) United States
(12) Patent Application Publication
(10) Pub. No.: US 2006/0196533 A1
(43) Pub. Date: Sep. 7, 2006

(54) Photoelectric conversion layer-stacked element and method for producing the same

(75) Inventor: Yoshiki Maehara, Minami-Ashigara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/362,776

(22) Filed: Feb. 28, 2006

(30) Foreign Application Priority Data
Feb. 28, 2005 (JP) P.2005-054685

(51) Int. Cl. H02N 6/00

(52) U.S. Cl. 136/243

(57) ABSTRACT

A photoelectric conversion element comprising: a pixel electrode; at least one photoelectric conversion layer containing an organic semiconductor; a transparent counter electrode; and a passivation layer containing an inorganic material, provided in this order.

### FIELD OF THE INVENTION

This invention relates to a photoelectric conversion layer-stacked solid-state image pickup element having a multilayer structure in the photoelectric conversion part. More specifically speaking, it relates to the passivation layer of a photoelectric conversion layer-stacked solid-state image pickup element using an organic semiconductor and a method of producing the same.

### BACKGROUND OF THE INVENTION

In a photoelectric conversion layer-stacked solid-state image pickup element having a multilayer structure in the photoelectric conversion part, use is made of an organic semiconductor in a photoelectric conversion layer (G layer) for converting green light (G) into a signal electric charge as, for example, in JP-A-2003-332551 (corresponding to US 2003/0209651 A1). Since organic semiconductors are easily deteriorated by moisture and gas (oxygen), a passivation layer should be formed in such an element with the use of an organic semiconductor, Although inorganic materials and organic materials commonly employed are cited as passivation layer materials in the description of JP-A-2003-332551, neither a specific material nor a layer-forming method is presented therein.

Although JP-A-2003-282250 relates not to a photoelectric conversion layer-stacked solid-state image pickup element but a device for forming passivation layers for organic EL elements and a method therefor, an inductively coupled plasma CVD (ICPCVD) method and a device for forming a passivation layer comprising a polymer, silicon nitride and silicon oxynitride on an organic EL element are disclosed therein. In JP-A-2003-282250, however, nothing is mentioned about the optical transparency of the passivation layer. Moreover, no specific working example is given therein.

Japanese Patent No. 3524711 and Japanese Patent No. 3577117 relate not to a photoelectric conversion layer-stacked solid-state image pickup element but a method of forming passivation layer for organic EL elements. Although the formation of a passivation layer made of silicon nitride, etc. on an organic EL element by the electron cyclotron resonance plasma CVO (ECRCVD) method is stated in these Patent Documents, nothing is mentioned about the optical transparency of the passivation layer.

### SUMMARY OF THE INVENTION

Accordingly, an object of the invention is to provide a material satisfying the following requirements that are necessary as a passivation layer of a photoelectric conversion layer-stacked solid-state image pickup element with the use of an organic semiconductor as reported in JP-A-2003-332551 and a method of producing the same.

Optical transparency: Since the passivation layer is located in the upper part of the organic semiconductor serving as a photoelectric conversion part via a transparent counter electrode, the material of the passivation layer should be transparent.

Conditions for forming passivation layer: The passivation layer is formed after forming a photoelectric conversion layer made of an organic semiconductor. It is therefore needed to select such conditions and means for forming the passivation layer that the organic semiconductor layer having been formed is not deteriorated thereby.

Barrier properties: In the steps of producing the solid-state image pickup element, the organic semiconductor should be protected from heat, plasma, solvents and so on (process resistance). After the fabrication, moreover, the organic semiconductor should be protected from deterioration by blocking moisture, gas, etc. (temporal stability).

These problems can be solved by the following means.
(1) A photoelectric conversion element comprising: a pixel electrode; at least one photoelectric conversion layer containing an organic semiconductor; a transparent counter electrode; and a passivation layer containing an inorganic material, provided in this order.
(2) The photoelectric conversion element as described in the above (1) wherein the inorganic material comprises a metal oxide and/or a metal nitride.
(3) The photoelectric conversion element as described in the above (2), wherein the inorganic material comprises silicon oxide (SiOₓ).
(4) The photoelectric conversion element as described in the above (2), wherein the inorganic material comprises silicon nitride (SiNₓ).
(5) The photoelectric conversion element as described in the above (2), wherein the inorganic material comprises silicon oxynitride (SiOₓN_{y}).
(6) The photoelectric conversion element as described in the above (2) , wherein the passivation layer has a stacked structure consisting of alternately stacked layers made of two materials selected from among silicon oxide, silicon nitride and silicon oxynitride.
(7) The photoelectric conversion element as described in any one of the above (1) to (6), wherein the passivation layer is formed in vacuo by a dry layer-formation method.
(8) The photoelectric conversion element as described in the above (7), wherein the dry layer-formation method is the plasma-enhanced chemical vapor deposition (plasma CVD) method.
(9) The photoelectric conversion element as described in the above (8), wherein the dry layer-formation method is the inductively coupled plasma CVD (ICPCVD) method.
(10) The photoelectric conversion element as described in the above (8), wherein the dry layer-formation method is the electron cyclotron resonance plasma CVD (ECRCVD) method.
(11) A method for producing a photoelectric conversion element including a pixel electrode, at least one photoelectric conversion layer containing an organic semiconductor, a transparent counter electrode, and a passivation layer containing an inorganic material, provided in this order, wherein the method comprises forming a passivation layer containing an inorganic material on a transparent counter electrode in vacuo by a dry layer-formation method.
(12) The method as described in the above (11), wherein the dry layer-formation method is the plasma-enhanced chemical vapor deposition (plasma CVD) method.
(13) The method as described in the above (12), wherein the dry layer-formation method is the inductively coupled plasma CVD method.
(14) The method as described in the above (12), wherein the dry layer-formation method is the electron cyclotron resonance plasma CVD method.
(15) A solid-state image pickup element comprising: an Si substrate including a CCD or CMOS signal transferring circuit; and the photoelectric conversion element as described in any one of the above (1) to (10).

According to the inventions (1) and (2), it is possible to provide a photoelectric conversion layer-stacked solid-state image pickup element with the use of an organic semiconductor which has a passivation layer capable of blocking factors causative of the deterioration of the organic semiconductor. Moreover, it is possible to provide a photoelectric conversion layer-stacked solid-state image pickup element which has a passivation layer having a particularly high transparency (according to the invention (3)), having particularly excellent properties of blocking factors causative of the deterioration of the organic semiconductor (according to the invention (4)), being excellent in both of transparency and blocking properties (according to the invention (5)), or having a combination of the advantages of individual materials (according to the invention (6)).

Furthermore, it is possible to provide a photoelectric conversion layer-stacked solid-state image pickup element having a passivation layer in which the element can be continuously fabricated in vacuo while preventing the contamination with factors (moisture, oxygen) causative of the deterioration of the organic semiconductor (according to the inventions (7) and (11)), layer formation can be practiced at a low (room) temperature so that the organic semiconductor is protected from heat deterioration during the fabrication (according to the inventions (8) and (12)), or a layer made of an inorganic material with favorable qualities (being excellent in transparency and blocking properties) can be formed (according to the inventions (9), (10), (13) and (14)).

### BRIEF DESCRIPTION OF THE DRAWINGS

FIG. 1 is a drawing which shows an example of the embodiment of the photoelectric conversion layer-stacked solid-state image pickup element of the invention using an organic semiconductor.

FIG. 2 is a drawing which shows an ICPCVD apparatus.

FIG. 3 is a drawing which shows an ECRCVD apparatus.

Description of the Reference Numerals and Signs:

### DETAILED DESCRIPTION OF THE INVENTION

(Photoelectric Conversion Element)

Next, the photoelectric conversion layer-stacked solid-state image pickup element (hereinafter referred to merely as “photoelectric conversion element” in some cases) of the invention will be illustrated.

The photoelectric conversion element comprises an electromagnetic wave absorption/photoelectric conversion part and a charge storage/transfer/reading part for the charge generated by the photoelectric conversion.

The electromagnetic wave absorption/photoelectric conversion part has a stacked structure composed of at least two layers whereby at least blue light, green light and red light can be absorbed and photoelectrically converted. The blue light absorption layer (B) can absorb light with wavelength of at least from 400 to 500 nm and the absorption index of the peak wavelength in this region is preferably 50% or more. The green light absorption layer (G) can absorb light with wavelength of at least from 500 to 600 nm and the absorption index of the peak wavelength in this region is preferably 50% or more. The red light absorption layer (R) can absorb light with wavelength of at least from 600 to 700 nm and the absorption index of the peak wavelength in this region is preferably 50% or more. These layers may be formed in any order. In a stacked structure composed of three layers, use may be made of the orders of, from the upper side, BGR, BRG, GBR, GRB, RBG and RGB. It is preferable that G is provided as the uppermost layer. In a stacked structure composed of two layers wherein an R layer is provided as the upper layer, BG layers are provided on a single plane to form the lower layer. In the case where a B layer is provided as the upper layer, GR layers are provided on a single plane to form the lower layer. In the case where a G layer is provided as the upper layer, BR layers are provided on a single plane to form the lower layer. It is preferable that the G layer is provided as the upper layer while the BR layers are provided as the lower layer. In such a case where two light absorption layers are provided on a single plane as the lower layer, it is preferable to form a filter layer (for example, in a mosaic structure) for color separation on the upper layer or between the upper and lower layers. It is also possible in some cases to form additional layer(s) as the fourth layer or higher or on the same plane.

The charge storage/transfer/reading part is provided under the electromagnetic wave absorption/photoelectric conversion part. It is preferred that the electromagnetic wave absorption/photoelectric conversion part in the lower layer also serves as the charge storage/transfer/reading part.

The electromagnetic wave absorption/photoelectric conversion part comprises an organic layer, an inorganic layer or a mixture of an organic layer with an inorganic layer. Organic layers may be B/G/R layers. Alternatively, inorganic layers may be B/G/R layers. A mixture of an organic layer with an inorganic layer is preferred. Fundamentally, one or two inorganic layers are formed in the case of forming an organic layer, and one inorganic layer is formed in the case of forming two organic layers. In the case of forming an organic layer and an inorganic layer, the inorganic layer forms electromagnetic wave absorption/photoelectric conversion parts in two or more colors on a single plane. It is preferable that the upper layer is an organic layer serving as the G layer while the lower layers are inorganic layers comprising the B layer and the R layer in this order from the upper side. It is also possible in some cases to form additional layer(s) as the fourth layer or higher or on the same plane. In the case where organic layers are B/G/R layers, the charge storage/transfer/reading part is formed under these layers. In the case of using an inorganic layer as the electromagnetic wave absorption/photoelectric conversion part, the inorganic layer also serves as the charge storage/transfer/reading part.

(Illustration of Organic Layer)

Now, the organic layer in the invention will be illustrated. In the invention, an electromagnetic wave absorption/photoelectric conversion part made of an organic layer comprises the organic layer located between a pair of electrodes. The organic layer is made up of an electromagnetic wave absorption part, an electron transportation part, a photoelectric conversion part, a hole transportation part, an electron blocking part, a hole blocking part, a crystallization prevention part, electrodes, an interlayer contact improvement part and so on which are piled up or mixed together. It is preferable that the organic layer contains an organic p-type compound or an organic n-type compound.

The organic p-type semiconductor (compound), which is a donor type organic semiconductor (compound), is typified mainly by a hole-transporting organic compound, i.e., an organic compound being liable to donate electron. To speak in greater detail, it means an organic compound having a lower ionization potential in the case of using two organic materials in contact with each other. That is to say, any compound capable of donating electron can be used as the donor type organic compound. For example, use can be made of triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonole compounds, polyamine compounds, indole compounds, pyrrole compounds, pyrazole compounds, polyarylene compounds, fused ring aromatic carbon ring compounds (naphthalene derivatives, anthracene derivatives, phenanthrene derivatives, tetracene derivatives, pyrene derivatives, perylene derivatives and fluoranthene derivatives), metal complexes having nitrogen-containing heterocyclic compounds as a ligand and so on. However, the invention is not restricted to these compounds and use may be made, as the donor type organic semiconductor, of any organic compound which has a lower ionization potential than the organic compound employed as the n-type (acceptor type) compound as discussed above.

The organic n-type semiconductor (compound), which is an acceptor type organic semiconductor (compound), is typified mainly by an electron-transporting compound, i.e., an organic compound being liable to accept electron. To speak in greater detail, it means an organic compound having a higher affinity in the case of using two organic materials in contact with each other. That is to say, any compound capable of accepting electron can be used as the acceptor type organic compound. For example, use can be made of fused ring aromatic carbon ring compounds (naphthalene derivatives, anthracene derivatives, phenanthrene derivatives, tetracene derivatives, pyrene derivatives, perylene derivatives and fluoranthene derivatives), 5- to 7-merbered heterocyclic compounds having a nitrogen atom, an oxygen atom or a sulfur atom (for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrralizine, pyrrolopyridine, thiadiazolopyridine, dibenzazepine and tribenzazepine), polyarylene compounds, fluorene compounds, cyclopentadiene compounds, silyl compounds, metal complexes having nitrogen-containing heterocyclic compounds as a ligand and so on. However, the invention is not restricted to these compounds and use may be made, as the acceptor type organic semiconductor, of any organic compound which has a higher affinity than the organic compound employed as the donor type organic compound as discussed above

Although any compounds are usable as the p-type organic dye or the n-type organic dye, preferable examples thereof include cyanine dyes, styryl dyes, hemicyanine dyes, merocyanine dyes (including zeromethine merocyanine (simple merocyanine)), three-nuclear merocyanine dyes, four-nuclear merocyanine dyes, rhodacyanine dyes, complex cyanine dyes, complex merocyanine dyes, aro polar dyes, oxonole dyes, hemioxonole dyes, squarium dyes, croconium dyes, azamethine dyes, coumarine dyes, arylidene dyes, anthraquinone dyes, triphenylmethane dyes, azo dyes, azomethine dyes, spiro compounds, metallocene dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dyes, metal complex dyes, fused ring aromatic carbon ring compounds (naphthalene derivatives, anthracene derivatives, phenanthrene derivatives, tetracene derivatives, pyrene derivatives, perylene derivatives and fluoranthene derivatives) and so on.

Next, a metal complex compound will be illustrated. A metal complex compound is a metal complex which carries a ligand having at least one nitrogen atom, oxygen atom or sulfur atom and coordinating with a metal. Although the metal ion in such a metal complex is not particularly restricted, preferable examples thereof include beryllium ion, magnesium ion, aluminum ion, gallium ion, zinc ion, indium ion and tin ion, still preferably beryllium ion, aluminum ion, gallium ion or zinc ion, and still preferably aluminum ion or zinc ion. As the ligand contained in the above metal complex, various publicly known ligands may be cited. For example, use can be made of ligands reported in Photochas try and Photophysics of Coordination Compounds, published by Springer-Verlag, H. Yersin (1987) and Yuki Kinzoku Kagaku-Kiso to Oyo, published by Shokabo, Akio Yamamoto (1982) and so on.

Preferable examples of the above ligand include nitrogen-containing heterocyclic ligands (preferably having from 1 to 30 carbon atoms, still preferably from 2 to 20 carbon atoms, and particularly preferably form 3 to 15 carbon atoms; including both of monodentate ligands and higher, bidentate ligands being preferred, e.g., pyridine ligands, bipyridyl ligands, quinolynol ligands, hydroxyphenylazole ligands such as hydroxyphenylbenzimidazole ligand, hydroxyphenylbenzoxazole ligand and hydroxyphenylirnidazole ligand), alkoxy ligands (preferably having from 1 to 30 carbon atoms, still preferably from 1 to 20 carbon atoms and particularly preferably from 1 to 10 carbon atoms, such as methoxy, ethoxy, butoxy and 2-ethylhyxyloxy), aryloxy ligands (preferably having from 6 to 30 carbon atoms, still preferably from 6 to 20 carbon atoms and particularly preferably from 6 to 12 carbon atoms, such as phenyloxy, 1-naphthyloxy, 2-naphthyloxy, 2,4,6-trimethylphenyloxy and 4-biphenyloxy), heteroaryloxy ligands (preferably having from 1 to 30 carbon atoms, still preferably form 1 to 20 carbon atoms and particularly preferably from 1 to 12 carbon atoms, such as pyridyloxy, pyrazyloxy, pyrimidyloxy and quinolyloxy), alkylthio ligands (preferably having from 1 to 30 carbon atoms, still preferably from 1 to 20 carbon atoms and particularly preferably from 1 to 12 carbon atoms, such as methylthio and ethylthio), arylthio ligands (preferably having from 6 to 30 carbon atoms, still preferably from 6 to 20 carbon atoms and particularly preferably from 6 to 12 carbon atoms, such as phenylthio), heterocycle-substituted thio ligands (preferably having from 1 to 30 carbon atoms, still preferably from 1 to 20 carbon atoms and particularly preferably from 1 to 12 carbon atoms, such as pyridylthio, 2-benzimidazolylthio, 2-benzoxazolylthio and 2-benzthiazolylthio) and siloxy ligands (preferably having from 1 to 30 carbon atoms, still preferably from 3 to 25 carbon atoms and particularly preferably from 6 to 20 carbon atoms, such as triphenylsiloxy group, triethoxysiloxy group and triisopropylsiloxy group). Still preferable examples thereof include nitrogen-containing heterocyclic ligands, aryloxy ligands, heteroaryloxy groups and siloxy ligands, and nitrogen-containing heterocyclic ligands, aryloxy ligands and siloxy ligands are still preferable.

In the invention, it is preferable to contain a photoelectric conversion layer (a photosensitive layer) which has a p-type semiconductor layer and an n-type semiconductor layer between a pair of electrodes and also has a bulk heterojunction layer containing the p-type semiconductor and the n-type semiconductor as an intermediate layer between these semiconductor layers. In this case, the shortage of the organic layer of having a short carrier diffusion length can be overcome owing to the bulk heterojunction structure in the organic layer and thus the photoelectric conversion efficiency can be elevated. The bulk heterojunction structure is described in detail in Japanese Patent Application No. 2004-080639.

It is preferable in the invention to contain a photoelectric conversion layer (a photosensitive layer which has two or more repeating structure units of a pn junction layer comprising a p-type semiconductor layer and an n-type semiconductor layer between a pair of electrodes (a tandem structure). It is still preferable to insert a thin layer made of an electrically conductive material between these repeating structure units. Although the number of the repeating structure units of the pn junction layers (the tandem structure) is not restricted, it preferably ranges from 2 to 50, still preferably from 2 to 30 and particularly preferably 2 or 10, from the viewpoint of achieving a high photoelectric conversion efficiency. As the electrically conductive material, silver or gold is preferable and silver is most desirable. The tandem structure is described in detail in Japanese Patent Application No. 2004-079930.

In a photoelectric conversion layer having a p-type semiconductor layer and an n-type semiconductor layer between a pair of electrodes (preferably a mixture/dispersion (bulk heterojunction) layer), a photoelectric conversion layer containing an organic compound having controlled orientation at least in one of the p-type semiconductor and the n-type semiconductor is preferable and a photoelectric conversion layer containing organic compounds having (possibly) controlled orientation in both of the p-type semiconductor and the n-type semiconductor is still preferred. As the organic compound to be used in the organic layer of the photoelectric conversion layer, it is preferable to employ one having a π-conjugated electron. It is favorable to use a compound having been oriented to give an angle of this n electron plane which is not perpendicular but as close to parallel as possible to the substrate (the electrode substrate). The angle to the substrate is preferably 0° or larger but not larger than 80°, still preferably 0° or larger but not larger than 60°, still preferably 0° or larger but not larger than 40°, still preferably 0° or larger but not larger than 20°, particularly preferably 0° or larger but not larger than 10° and most desirably 0° (i.e., being parallel to the substrate). The organic layer comprising the organic compound with controlled orientation as described above may be at least a part of the whole organic layer. It is preferable that the part with controlled orientation amounts to 10% or more based on the whole organic layer, still preferably 30% or more, still preferably 50% or more, still preferably 70% or more, particularly preferably 90% or more and most desirably 100%. In this construction, the shortage of the organic layer of having a short carrier diffusion length can be overcome by controlling the orientation of the organic compound in the organic layer and thus the photoelectric conversion efficiency can be elevated.

In the where the organic compound has controlled orientation, it is still preferable that the heterojunction plane (for example, a pn junction plane) is not parallel to the substrate. It is favorable that the organic compound is oriented so that the heterojunction plane is not parallel to the substrate (the electrode substrate) but as close to perpendicular as possible thereto. The angle to the substrate is preferably 10° or larger but not larger than 90°, still preferably 30° or larger but not larger than 90°, still preferably 50° or larger but not larger than 90°, still preferably 70° or larger but not larger than 90°, particularly preferably 80° or larger but not larger than 90° and most desirably 90° (i.e., being perpendicular to the substrate). The layer of the compound with controlled heterojunction plane as described above may be a part of the whole organic layer. The part with controlled orientation preferably amounts to 10% or more based on the whole organic layer, still preferably 30% or more, still preferably 50% or more, still preferably 70% or more, particularly preferably 90% or more and most desirably 100%. In such a case, the area of the heterojunction plane in the organic layer is enlarged and, in its turn, electrons, holes, electron-hole pairs, etc. formed in the interface can be carried in an increased amount, which makes it possible to improve the photoelectric conversion efficiency. The photoelectric conversion layer (a photosensitive layer) in which the orientation is controlled in both of the heterojunction plane and the π-electron plane as described above, the photoelectric conversion efficiency can be particularly improved. These states are described in detail in Japanese Patent Application No. 2004-079931.

From the viewpoint of light absorption, a larger thickness of an organic dye layer is preferred. By taking the percentage not contributing to charge separation into consideration, however, the layer thickness of the organic dye layer according to the invention is preferably 30 nm or more but not more than 300 nm, still preferably 50 nm or more but not more than 250 nm, and particularly preferably 80 nm or more but not more than 200 nm.

[Method of Forming Organic Layer]

The layers containing these organic compounds can be formed by a dry layer-forming method or a wet layer-forming method. Specific examples of the dry layer-forming method include physical vapor phase epitaxy methods such as the vacuum vapor deposition method, the sputtering method, the ion plating method and the MBE method, and CVD methods such as the plasma polymerization method. Examples of the wet layer-forming method include the casting method, the spin. coating method, the dipping method and the LB method:

In the case of using a polymer compound as at least one of the p-type semiconductor (compound) and the n-type semiconductor (compound), it is favorable to form the layer by a wet layer-forming method which can be easily carried out. When a dry layer-forming method such as the vapor deposition method is employed, it is highly difficult to employ a polymer compound because of a fear of decomposition. In such a case, use may be preferably made of a corresponding oligomer as a substitute for the polymer. In the case of using a low-molecular weight compound in the invention, use is preferably made of a dry layer-forming method and the vacuum vapor deposition method is particularly preferred. Fundamental parameters in the vacuum vapor deposition method include a method of heating a compound (e.g., the resistance heating method, the electron beam heating/deposition method or the like), the shape of the deposition source such as a crucible or a boat, the degree of vacuum, the deposition temperature, the substrate temperature, the deposition speed and so on. To achieve uniform deposition, it is favorable to carry out the deposition while rotating the substrate. A higher degree of vacuum is preferred. The vacuum vapor deposition is performed at a degree of vacuum of preferably 10⁻² Pa or lower, more preferably 10⁻⁴ Pa or lower and particularly preferably 10⁻⁶ Pa or lower. It is preferable to carry out all of the vapor deposition steps in vacuo. Fundamentally, the subject compound should be prevented from direct contact with the external oxygen or moisture. The vacuum vapor deposition conditions as described above should be strictly controlled, since the crystalinity, amorphous properties, density and denseness of the organic layer are affected thereby. It is preferable to PI or PID control the deposition speed with the use of a layer thickness monitor such as a crystal oscillator or an interferometer. In the case of depositing two or more compounds at the same time, use may be preferably made of the co-deposition method, the flash deposition method or the like.

(Electrode)

The electromagnetic wave absorption/photoelectric conversion part comprising organic layers according to the invention is located between a pair of electrodes respectively serving as a pixel electrode and a counter electrode. It is preferable that the lower layer serves as the pixel electrode.

It is preferable that the counter electrode takes out positive holes from a hole-transporting photoelectric conversion layer or a hole-transporting layer. As a material of the counter electrode, use may be made of a metal, an alloy, a metal oxide, an electrically conductive compound or a mixture thereof. It is preferable that the pixel electrode can take out electrons from an electron-transporting photoelectric conversion layer or an electron-transporting layer. It is selected by considering the adhesiveness to the adjacent layers such as the electron-transporting photoelectric conversion layer and the electron-transporting layer, electron affinity, ionization potential, stability and so on. Specific examples thereof include electrically conductive metal oxides such as tin oxide, zinc oxide, indium oxide and indium tin oxide (ITO), metals such as gold, silver, chromium and nickel, mixtures or stacks of these metals with electrically conductive metal oxides, inorganic conductive materials such as copper iodide and copper sulfide, organic conductive materials such as polyaniline, polythiophene and polypyrrole, silicon compounds and stacks thereof with ITO. Electrically conductive metal oxides are preferable and ITO and IZO are still preferable from the viewpoints of productivity, high conductivity, transparency and so on. The layer thickness may be appropriately selected depending on material. In usual, it is 10 nm or more but not more than 1 μm, still preferably 30 nm or more but not more than 500 nm and still preferably 50 nm or more but not more than 300 nm.

The pixel electrode and the counter electrode may be constructed by various methods depending on materials. In the case of using ITO, for example, a layer may be formed by the electron beam heat deposition method, the sputtering method, the resistance heat deposition method, the chemical reaction method (sol-gel method, etc.) or the method of coating with an indium tin oxide dispersion. In the case of using ITO, it is also possible to perform the UV-ozone treatment, the plasma treatment or the like.

It is preferable to construct a transparent electrode layer under plasma-free conditions. By constructing the transparent electrode layer under plasma-free conditions, effects of plasma on the substrate can be minimized and thus favorable photoelectric conversion characteristics can be established The term “plasma-free” as used herein means a state wherein no plasma generates in the course of forming a transparent electrode layer or the distance between a plasma source and a substrate is 2 cm or longer, preferably 10 cm or longer and still preferably 20 cm or longer and, therefore, plasma is lessened until it reaches the substrate.

As a device wherein no plasma generates during the layer-formation of a transparent electrode layer, use can be made of, for example, an electron beam heat deposition device (an EB deposition device) and a pulse laser deposition device. Namely, use can be made of an EB deposition device or a pulse laser deposition device reported in Tomei Dodenmaki no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and reference documents attached thereto. A method of forming a transparent electrode layer by using an EU deposition device will be called the EE deposition method while a method of forming a transparent electrode layer with the use of a pulse laser deposition device will be called the pulse laser deposition method hereinafter.

As examples of a device having a distance between a plasma source and a substrate of 2 cm or longer and, therefore, plasma is lessened until it reaches the substrate (hereinafter referred to as a plasma-free layer forming device), a counter target sputtering device and an arc plasma deposition device may be cited. Namely, use can be made of devices reported in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and reference documents attached thereto.

Now, the electrodes in the electromagnetic wave absorption/photoelectric conversion part of the invention will be illustrated in greater detail. The photoelectric conversion layer in the organic layer, which is located between a pixel electrode layer and a counter electrode layer, may comprise an interelectrode material or the like. The term “pixel electrode layer” means an electrode layer constructed in the upper part of the substrate on which a charge storage/transfer/reading part is formed. It is usually divided for individual pixels so that a signal charge converted by the photoelectric conversion layer can be read for each pixel on the charge storage/transfer/signal reading circuit substrate to give an image.

The term “counter electrode layer” means an electrode layer having a function of sandwiching the photoelectric conversion layer together with the pixel electrode layer to thereby emit a signal charge having a polarity opposite to the signal charge. Since it is unnecessary to divide the emission of the signal charge for individual pixels, pixels usually have a counter electrode layer in common. Thus, it is sometimes called a common electrode layer.

The photoelectric conversion layer is located between the pixel electrode layer and the counter electrode layer. The photoelectric conversion function is established by the photoelectric conversion layer, the pixel electrode layer and the counter electrode layer.

In the case where a single organic layer is piled on a substrate, the photoelectric conversion layer stack is composed of, for example, a substrate and a pixel electrode layer (fundamentally being a transparent electrode layer), a photoelectric conversion layer and a counter electrode layer (a transparent electrode layer) which are stacked on the substrate in this order, though the invention is not restricted thereto.

In the case where two organic layers are piled on a substrate, the photoelectric conversion layer stack is composed of, for example, a substrate and a pixel electrode layer (fundamentally being a transparent electrode layer), a photoelectric conversion layer, a counter electrode layer (a transparent electrode layer), an interlayer insulating layer, a pixel electrode layer (fundamentally being a transparent electrode layer), a photoelectric conversion layer and a counter electrode layer (a transparent electrode layer) which are stacked on the substrate in this order.

The material of the transparent electrode layer constituting the photoelectric conversion part in the invention is preferably a material which is usable in layer-formation by using a plasma-free layer forming device, an EB deposition device or a pulse laser deposition device. Preferable examples thereof include metals, alloys, metal oxides, metal nitrides, metal borides, organic conductive compounds and mixtures thereof. Specific examples thereof include conductive metal oxides such as tin oxide, zinc oxide, indium oxide, indium zinc oxide (IZO), indium tin oxide (ITO) and indium tungsten oxide (IWO), metal nitrides such as titanium nitride, metals such as gold, platinum, silver, chromium, nickel and aluminum, mixtures or stacks of these metals with conductive metal oxides, inorganic conductive substances such as copper iodide and copper sulfide, organic conductive substances such as polyaniline, polythiophene and polypyrrole, stacks thereof with ITO, and so on. Also, use may be made of materials reported in detail in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and so on.

As the transparent electrode layer material, it is particularly preferable to use any of ITO, IZO, SnO₂, ATO (antimony-doped tin oxide), ZnO, AZO (Al-doped zinc oxide), GZO (gallium-doped zinc oxide), TiO₂ and FTO (fluorine-doped tin oxide). The light transmittance of a transparent electrode layer at the photoelectric conversion light absorption peak wavelength of the photoelectric conversion layer contained in the photoelectric conversion element having the transparent electrode layer is preferably 60% or more, still preferably 80% or more, still preferably 90% or more and still preferably 95% or more. The preferable range of the surface resistance of the transparent electrode layer varies depending on, for example, whether being a pixel electrode or a counter electrode and whether the charge storage/transfer/reading part having a CCD structure or a CMOS structure. In the case of using the transparent electrode layer as a counter electrode and the charge storage/transfer/reading part having a CMOS structure, the surface resistance is preferably not more than 10000 Ω/□, still preferably not more than 1000 Ω/□. In the case of using the transparent electrode layer as a counter electrode and the charge storage/transfer/reading part having a CCD structure, the surface resistance is preferably not more than 1000 Ω/□, still preferably not more than 100 Ω/□. In the case of using as a pixel electrode, the surface resistance is preferably not more than 1000000 Ω/□, still preferably not more than 100000 Ω/□.

Now, layer-forming conditions for the transparent electrode layer will be described. In the layer-forming step of the transparent electrode layer, the substrate temperature is preferably 500° C. or below, still preferably 300° C. or below, still preferably 200° C. or below and still preferably 150° C. or below. A gas may be introduced during the transparent electrode layer formation. Although the gas is not fundamentally restricted in species, use may be made of Ar, He, oxygen, nitrogen or the like. It is also possible to use a mixture of these gases. In the case of using an oxide material, it is preferable to use oxygen since there frequently arises oxygen defect.

It is preferable to apply a voltage to the photoelectric conversion layer of the invention to improve the photoelectric conversion efficiency. Although the application voltage may be an arbitrary one, the required voltage level varies depending on the layer thickness of the photoelectric conversion layer. That is to say, a higher photoelectric conversion efficiency is obtained under the larger electric field applied to the photoelectric conversion layer. In the case of applying a definite voltage, the electric field is elevated with a decrease in the layer thickness of the photoelectric conversion layer. In the case of using a thin photoelectric conversion layer, therefore, the applied voltage may be relatively low. The electric field to be applied to the photoelectric conversion layer is preferably 10 V/m or more, still preferably 1×10³ V/m or more, still preferably 1×10⁵ V/m or more, particularly preferably 1×10⁶ V/m or more and most desirably 1×10⁷ V/m or more. Although the upper limit thereof is not particularly specified, it is undesirable to apply an excessive electric field since a current flows even in a dark place in such a case. Thus, the electric field to be applied is preferably 1×10¹² V/M or less, still preferably 1×10⁹ V/m or less.

(Inorganic Layer)

Now, an inorganic layer serving as the electromagnetic wave absorption/photoelectric conversion part will be illustrated. In this case, light passing through the upper organic layer is photoelectrically converted in the inorganic layer. As the inorganic layer, use is generally made of a pn junction or a pin junction of semiconductor compounds such as crystalline silicon, amorphous silicon and GaAs. As a stacked structure, a method disclosed by U.S. Pat. No. 5,965,875 may be employed. Namely, this method comprises forming a photo acceptance part stacked with the use of the wavelength-dependency of the absorption coefficient of silicon and performing color separation in the depth direction thereof. Since the color separation is carried out depending on the light transmission depth of silicon in this case, the spectra detected in individual acceptance parts stacked together have each a broad range. By using the organic layer as the upper layer as described above (i.e., detecting light transmitting the organic layer in the depth direction of silicon), however, the color separation can be remarkably improved. By providing a G layer as the organic layer, in particular, light transmitting through the organic layer is separated into B light and R light. As a result, the light may be divided merely into BR lights in the depth direction of silicon and thus the color separation is improved. In the case where the organic layer is a B layer or an R layer, the color separation can be remarkably improved too by appropriately selecting the electromagnetic wave absorption/photoelectric conversion part of silicon along the depth direction. In the case of forming two organic layers, the function as the electromagnetic wave absorption/photoelectric conversion part in silicon may be performed fundamentally in only one color and, in its turn, favorable color separation can be established.

In a preferable case, the inorganic layer has a structure wherein multiple photodiodes are stacked in the depth direction of a semiconductor substrate for individual pixels and color signals corresponding to the signal charges generating in the individual photodiodes due to light absorbed by the multiple photodiodes are read out. It is preferable that the multiple photodiodes involve at least one of a first photodiode located in the depth of absorbing B light and a second photodiode located in the depth of absorbing R light, and each of the photodiodes has a color signal reading circuit for reading a color signal corresponding to each of the signal charges. According to this constitution, color separation can be performed without resorting to a color filter. It is also possible in some cases to detect light in the negative component, which enables color image pickup with favorable color reproducibility. It is preferable in the invention that the joint part of the first photodiode is formed in a depth up to about 0.2 μm from the semiconductor substrate surface, while the joint of the second photodiode is formed in a depth up to about 2 μm from the semiconductor substrate surface.

Now, the inorganic layer will be illustrated in greater detail. Preferable examples of the inorganic layer constitution include photo acceptance elements of the photoconductive type, the p-n junction type, the shot-key junction type, the PIN junction type and the MSM (metal-semiconductor-metal) junction type and photo acceptance elements of the photo transistor type. It is preferable in the invention to employ a photo acceptance element wherein first conductive areas and second conductive areas being opposite to the first conductive areas are alternatively stacked on a single semiconductor substrate and the joint parts of the first conductive areas and the second conductive areas are formed respectively at depths appropriate mainly for the photoelectric conversion of a plural number of lights in different wavelength regions. As the single semiconductor substrate, monocrystalline silicon may be preferably employed. Thus, color separation can be performed by taking advantage of the absorption wavelength characteristics depending on the depth direction of the silicon substrate.

As the inorganic semiconductor, use can be made of InGaN-based, InAlN-based, In AlP-based or InGaAlP-based inorganic semiconductors. An InGaN-based inorganic semiconductor is prepared by appropriately altering the composition of In so as to achieve an absorption peak in the blue light wavelength region. That is to say, it is represented by In_{X}Ga_{1-X}N (0≦X<1). A semiconductor made of such a compound can be produced by the organic metal vapor phase epitaxy method (MOCVD method). An InAlN-based nitride semiconductor with the use of Al belonging to the same group (13) as Ga is also usable as a short wavelength light acceptor part as in the InGaN-based one. Furthermore, use can be also made of InAlP and InGaAlP lattice-matching a GaAs substrate.

The inorganic semiconductor may have an embedded structure. The term “embedded structure” means a constitution wherein both ends of a short wavelength light acceptor part are covered with a semiconductor which is different from the short wavelength light acceptor part. As the semiconductor covering both ends, it is preferable to employ a semiconductor having a band gap wavelength which is shorter than the band gap wavelength of the short wavelength light acceptor part or equals thereto.

The organic layer and the inorganic layer may be bonded in an arbitrary manner. It is preferable to provide an insulating layer between the organic layer and the inorganic layer to thereby electrically insulating them.

An npn-junction or a pnpn-junction, from the incident light side, is preferred. The pnpn-junction is still preferred, since the surface potential can be maintained at a high level by forming a p layer on the surface and thus holes and a dark current generating on the surface can be trapped, thereby lowering the dark current.

In such a photodiode, an n-type layer, a p-type layer, an n-type layer and a p-type layer are deeply formed in this order, i.e., being successively diffused from the p-type silicon substrate surface, and thus a pn-junction diode is formed in the depth direction of the silicon to give four layers (pnpn). Incident light with a longer wavelength entering from the diode surface side the more deeply transmits and the incident wavelength and the attenuation coefficient are inherent to silicon. Thus, the diode is designed so that the pn junction face covers the wavelength region of visible light. Similarly, an n-type layer, a p-type layer and an n-type layer are formed in this order to give a junction diode having three layers (npn). A light signal is taken out from the n-type layer, while the p-type layer is ground connected.

By forming a drawing electrode in each area and applying a definite reset potential thereto, each area becomes depletion and the capacity in each junction part is highly lessened. Thus, the capacity generating in the junction face can be highly lessened.

(Auxiliary Layer)

It is preferable in the invention to provide an ultraviolet absorption layer and/or an infrared absorption layer as the uppermost layer of the electromagnetic wave absorption/photoelectric conversion part. The ultraviolet absorption layer can absorb or reflect light having wavelength of at least 400 nm or less and it preferably has an absorption index in a wavelength region of 400 nm or less of 50% or more. The infrared absorption layer can absorb or reflect light having wavelength of at least 700 nm or more and it preferably has an absorption index in a wavelength region of 700 nm or more of 50% or more.

These ultraviolet absorption layer and infrared absorption layer can be formed by publicly known methods. For example, there has been known a method which comprises forming a mordant layer made of a hydrophilic polymer such as gelatin, casein, glue or polyvinyl alcohol on the substrate and adding a dye having a desired absorption wavelength to the mordant layer or dyeing the mordant layer to form a color layer. Another known method comprises using a colored resin wherein a specific coloring matter is dispersed in a transparent resin. Moreover, use may be made of a colored resin layer comprising a mixture of a polyamino resin with a coloring matter, as reported by JP-A-58-46325, JP-A-60-78401, JP-A-60-184202, JP-A-60-184203, JP-A-60-184204, JP-A-60-184205 and so on. It is also possible to use a coloring agent comprising a photosensitive polyimide resin.

Furthermore, it is possible to disperse a coloring matter in an aromatic polyamide resin which has a photosensitive group in its molecule and can provide a hardened layer at 200° C. or below, as reported by JP-B-7-113685. Also, use can be made of a dispersion colored resin in an amount as specified in JP-B-7-69486.

In the invention, it is preferable to use a dielectric multiple layers. The advantage of using a dielectric multiple layers resides in that it has a sharp wavelength-dependency of light transmission.

It is preferable that individual electromagnetic wave absorption/photoelectric conversion parts are separated by insulating layers. These insulating layers can be formed by using transparent insulating materials such as glass, polyethylene, polyethylene terephthalate, polyether sulfone or polypropylene. Also, use may be preferably made of silicon nitride, silicon oxide and the like. A silicon nitride layer formed by the plasma CVD method is preferably used because of being highly dense and highly transparent.

Furthermore, it is preferable to employ an embodiment wherein a microlens array is formed in the upper part of the photo acceptance element so as to improve the light collection efficiency.

(Charge Storage/Transfer/Reading Part)

Concerning the charge storage/transfer/reading part, reference may be made to JP-A-58-103166, JP-A-58-103165, JP-A-2003-332551 and so on. Namely, use may be appropriately made of a constitution wherein MOS transistors are formed for individual pixels on a semiconductor substrate or a constitution having CCD as an element. In the case of a photoelectric conversion element with the use of MOS transistors, for example, electric charge arises in a photoconductive layer due to incident light transmitting through electrodes. By applying a voltage to the electrodes, an electric field is formed between the electrodes and thus the charge migrates across the photoconductive layer toward the electrodes. Then the charge enters into a charge storage part in the MOS transistor and stored therein. The charge stored in the charge storage part transfers to a charge-reading part by switching the MOS transistor and then output as an electric signal. Owing to this mechanism, a full color image signals are input in the solid-state image pickup device having a signal processing part.

It is also possible that a definite amount of bias charge is injected into a storage diode (a refresh mode) and, after storing a definite charge (a photoelectric conversion mode), the signal charge is read out. It is possible to use a photo acceptance element per se as a storage diode or to separately provide a storage diode.

Next, signal reading will be illustrated in greater detail. Signals can be read by using a conventional color reading circuit. A signal charge or a signal current photoelectrically converted in the photo acceptance part is stored in the photo acceptance part per se or a capacitor provided separately. The thus stored charge is read simultaneously with the selection of pixel position by the means of MOS image pickup element with the use of the X-Y address system (a so-called CMOS sensor). As another reading method, an address selection system which comprises successively selecting pixels one by one with a multi prexar switch and a digital shift switch and reading as a signal voltage (or charge) along a common output curve may be cited. There is an image pickup element with the use of a two-dimensionally arrayed X-Y address operation which is known as a CMSO sensor. In this element, a switch attached to the X-Y intersection is connected to a perpendicular shift resistor. When the switch is turned on by the voltage from the perpendicular scanning shift resistor, signals read from pixels in the same line are read along the output curve in the ray direction. These signals are read one by one from the output end through a switching mechanism which is driven by a horizontal scanning shift resistor.

To read output signals, use can be made of a floating diffusion detector or a floating gate detector. Moreover, S/N can be improved by providing pixels with a signal amplification circuit or using the correlated double sampling method.

Signals can be processed by using gamma correlation with the use of an ADC circuit, digitalization with the use of an AD converter, the luminance signal processing method or the color signal processing method. Examples of the color signal processing method include white balance processing, color separation processing, color matrix processing and so on. In order to use as NTSC signals, the RGB signals can be converted into YIQ signals.

In the charge transfer/reading part, the charge migration rate should be 100 cm²/volt sec or higher. Such a migration rate can be established by selecting an appropriate semiconductor material belonging to the group IV, III-V or II-VI. Among all, it is preferable to employ silicon semiconductors, since fine processing techniques have advanced in this field and they are available at low cost. There have been proposed a large number of charge transfer/charge reading systems and any of these systems is usable. A CMSO-type or CCD-type device system is particularly preferred. In the invention, the CMSO-type system is preferred in various points including high-speed reading, pixel integration, partial reading and power consumption.

(Connection)

Multiple parts for connecting the electromagnetic wave absorption/photoelectric conversion part to the charge storage/transfer/reading part may be made of any metal. It is preferable to use a metal selected from among copper, aluminum, silver, gold, chromium and tungsten and copper is particularly preferable therefor, Contact parts should be respectively provided between individual electromagnetic wave absorption/photoelectric conversion parts and individual charge storage/transfer/reading parts. In the case of using a stacked structure comprising blue, green and red light photosensitive units, it is necessary to connect a fetch electrode for blue light to a charge transfer/reading part, to connect a fetch electrode for green light to a charge transfer/reading part and to connect a fetch electrode for red light to a charge transfer/reading part respectively.

(Process)

The stacked photoelectric conversion element according to the invention can be fabricated in accordance with a so-called micro fabrication process employed in producing publicly known integrated circuits and so on. In this process, the following procedures are repeated fundamentally: pattern exposure with the use of active rays or electron beams (i, g bright-line of mercury, eximer laser, X-ray, electron beams, etc.); pattern formation by development and/or burning; provision of element-forming materials (coating, vapor deposition, sputtering, CV, etc.); and removal of the materials from non-pattern areas (heating, dissolution, etc.).

(Use)

Concerning the chip size, the device may have the brownie size, the 135 size, the APS size, the 1/1.8 size or a smaller size. In the stacked photoelectric conversion element of the invention, the pixel size is expressed in diameter of a circle corresponding to the maximum area of multiple electromagnetic wave absorption/photoelectric conversion parts. Although any pixel size may be used, a pixel size of 2 to 20 μm is preferable, still preferably 2 to 10 μm and particularly preferably 3 to 8 μm.

In the case where the pixel size exceeds 20 μm, the resolution is lowered. In the case where the pixel size is less than 2 μm, the resolution is also lowered due to radio interference among sizes.

The photoelectric conversion element of the invention is usable in digital still cameras. It is also preferably usable in TV cameras. In addition thereto, the photoelectric conversion element of the invention is usable in digital video cameras, monitor cameras (to be used in, for example, office buildings, parking areas, financial institutions, automatic loan-application machines, shopping centers, convenience stores, outlet malls, department stores, pinball parlors, karaoke boxes, game centers and hospitals), other various sensors (entrance monitors, identification sensors, sensors for factory automation, robots for household use, robots for industrial use and pipe inspection systems), medical sensors (endoscopes and fundus cameras), TV conference systems, TV telephones, camera-equipped cell phones, safe driving systems for automobiles (back guide monitors, collision-estimating systems and lane-keeping systems), sensors for TV games and so on.

Among all, the photoelectric conversion element of the invention is appropriately usable in TV cameras. This is because the photoelectric conversion element of the invention requires no optical system for color separation and thus contributes to the reduction in size and weight of TV cameras. Moreover, it has a high sensitivity and a high resolution and, therefore, is particularly preferable in TV cameras for high-definition broadcast. The TV cameras for high-definition broadcast as used herein include cameras for digital high-definition broadcast.

The photoelectric conversion element of the invention requires no optical low pass filter, which makes it further preferable from the viewpoint of achieving an elevated sensitivity and improved resolution.

Furthermore, the thickness of the photoelectric conversion element according to the invention can be lessened and no optical system for color separation is required therein. Thus, it can provide a single camera which meets various photography-related needs. Namely, scenes wherein different sensitivities are needed, e.g., “environments with a change in brightness, e.g., daytime and night”, “a still subject and a moving subject” and so on, and scenes wherein different spectral sensitivities or color reproductions are needed can be taken with the use of a single camera merely replacing the photoelectric conversion elements of the invention. Therefore, it becomes unnecessary to carry a plural number of cameras, which lessen the load on a photographer. To replace the photoelectric conversion elements, the above-described photoelectric conversion element is prepared together with spare photoelectric conversion elements for, e.g., infrared light photographing, monochromic photographing, dynamic range replacement and so on.

The TV camera according to the invention can be fabricated by reference to Terebijon Kamera no Sekkei Gijutsu, ed. by The Institute of Image Information and Television Engineers (1999, Corona) chap, 2 and replacing, for example, the optical system for color separation and the image pickup device in FIG. 2.1 (Fundamental Constitution of TV Camera) therein by the photoelectric conversion element of the invention.

The stacked photo acceptance elements as described above may be used as an image pickup element by aligning. Alternatively, a single device can be used as a photo sensor or a color photo acceptance element in biosensors and chemical sensors.

(Preferable Photoelectric Conversion Element According to the Invention)

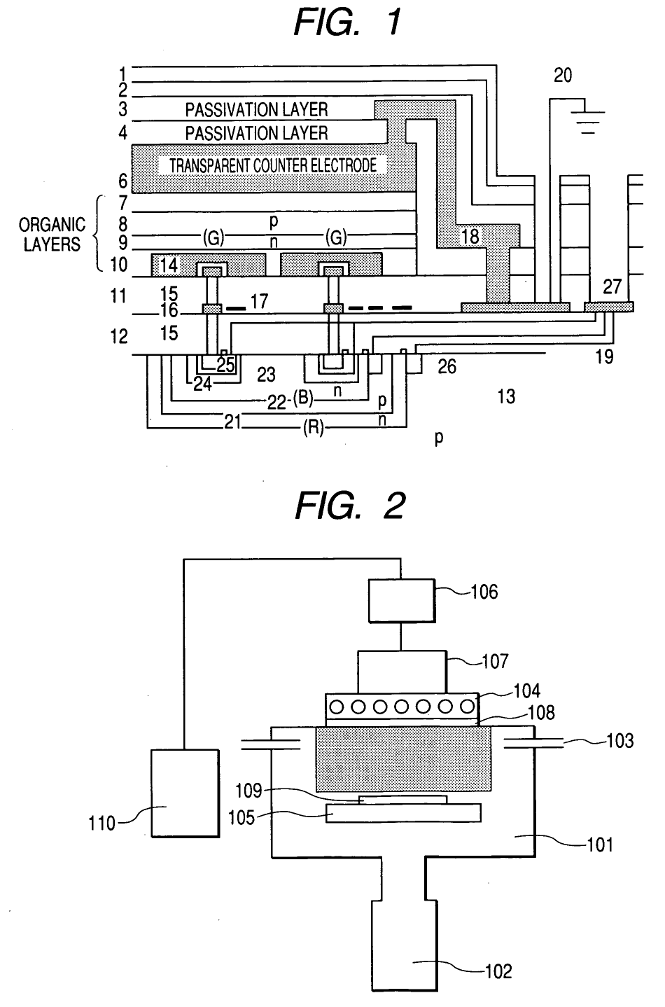

Next, a preferable photoelectric conversion element of the invention will be illustrated by referring to FIG. 1. In FIG. 1, 13 stands for a monocrystalline silicon base which also serves as electromagnetic wave absorption/photoelectric conversion parts for B light and R light and a charge storage/transfer/reading part for the charge generated by photoelectric conversion A p-type silicon substrate is usually employed therefor. 21, 22 and 23 respectively show an n layer, a p layer and another n layer formed in the silicon base. The n layer 21 is an R light signal charge storage part in which R light signal charge photoelectrically converted by the pn junction is stored. The thus stored charge is connected to a signal-reading pad 27 by a metal wiring 19 via a transistor 26. The n layer 23 is a B light signal charge storage part in which B light signal charge photoelectrically converted by the pn junction is stored. The thus stored charge is coninected to the signal-reading pad 27 by the metal wiring 19 via a transistor similar to the transistor 26. Although the player, n layers, transistors, metal wirings, etc. are schematically indicated therein, each member has an appropriately selected structure, etc. as discussed above. Since B light and R light

[symbol]

tungsten, aluminum or the like as the main component. A less thickness of the layer 12 is preferred. Namely, its thickness is 3 μm or less, preferably 2 μm or less and still preferably 1 μm or less. It is preferable to provide a signal reading pad 27 for each of B, G and R signals. The above described process can be carried out by a publicly known process, i.e., the so-called CMOS process.

The electromagnetic wave absorption/photoelectric conversion parts of G light are represented by 6, 7, 8, 9, 10 and 14. The electromagnetic wave absorption/photoelectric conversion parts 6 and 14 are transparent electrodes which correspond respectively to a counter electrode and a pixel electrode. Although the pixel electrode 14 is a transparent electrode, it is frequently needed to provide a part made of aluminum, molybdenum, etc. to the connection area so as to achieve favorable electrical connection to a plug 15. A bias is loaded on these transparent electrodes via the wirings from a connection electrode 18 and the counter electrode pad 20. In a preferred structure, positive bias is loaded on the pixel electrode 14 to the counter electrode 5 and thus electrons are stored in 25. In this case, 7 serves as an electron blocking layer, 8 serves as a p layer, 9 serves as an n layer and 10 serves as a hole blocking layer, thus showing a typical layer structure of the organic layers. The total thickness of the organic layers 7, 8, 9 and 10 is preferably 0.5 μm or less, still preferably 0.3 μm or less and particularly preferably 0.2 μm or less. The thicknesses of the transparent counter electrode 6 and the transparent pixel electrode 14 are preferably 0.2 μm or less. 3 and 4 stand for passivation layers comprising silicon nitride, etc. as the main component. Owing to these passivation layers, the process for producing the layers including the organic layers becomes easy. These layers particularly contribute to the relief in damages on the organic layers in the course of the resist pattern formation, etching, etc. in constructing the connection electrodes such as 18. It is also possible to employ a fabrication process with the use of a mask to omit the steps of forming a resist pattern and etching. The thicknesses of the passivation layers 3 and 4 are preferably 0.5 μm or less, so long as the above-described requirements are fulfilled.

3 represents a passivation layer of the connection electrode 18. 2 represents a stack composed of an infrared-cutting dielectric multiple layers and an ultraviolet-cutting layer. 1 represents an antireflective layer. It is preferable that the total thickness of the layers 1, 2 and 3 is 1 μm or less.

In the photoelectric conversion element shown in FIG. 1 as described above, four G pixels are employed per B pixel and R pixel, One G pixel may be used per B pixel and K pixel. Three C pixels may be used per B pixel and R pixel. Two G pixels may be used per B pixel and R pixel. Moreover, other arbitrary combinations may be employed. Although a preferred embodiment of the invention has been described above, the invention is not restricted thereto.

The passivation layer of the invention is a passivation layer which is made of an inorganic material and formed in vacuo by the dry layer-formation method above the transparent counter electrode provided on the photoelectric conversion layer made of an organic semiconductor of the photoelectric conversion layer-stacked solid-state image pickup element.

Next, the passivation layer of the invention will be illustrated in greater detail by reference to FIG. 1.

Passivation layers 3 and 4 are located above the counter electrode 6 while a connection electrode 18 should be located between the passivation layers 3 and 4. In particular, the passivation layer 4 is to be subjected to the patterning of the passivation layer 4 per se (for electrically connecting the connection electrode 18, the transparent counter electrode 6, the counter electrode pad 20 and the signal reading pad 27) and photolithography step (resist-coating, development, etching and resist stripping (i.e., resist ashing)) for the fine processing (patterning) of the connection electrode 18, it should protect the organic semiconductor from heat, solvents such as water and plasma. On the other hand, the passivation layer 3 is to be subjected to the photolithography step in the patterning the counter electrode pad 20 and the signal reading pad 27. Thus, it should protect the organic semiconductor from heat, solvents such as water and plasma, similar to the passivation layer 4. The passivation layer 3 has an additional role of blocking moisture, gas and so on and thus preventing deterioration of the organic semiconductor and the connection electrode 18 after the fabrication (temporal stability). It is sometimes necessary, depending on the material of the infrared-cutting dielectric multiple layers, to further provide a passivation layer on the multiple layers 2.

In the case two or more photoelectric conversion layers containing an organic semiconductor are stacked, it is necessary to provide a longitudinal wiring penetrating through the intermediate photoelectric conversion layer to thereby connect the transparent pixel electrode of the upper layer to the signal-reading circuit on the silicon substrate. Thus, the photoelectric conversion layer and the transparent counter electrode should be patterned at every intermediate photoelectric conversion layer formation. Since the photolithography step is employed in this course, a passivation layer for protecting the organic semiconductor from heat, solvents such as water and plasma should be provided on the transparent counter electrode.

[Inductively Coupled Plasma CVD]

FIG. 2 shows an ICPCVD (inductively coupled plasma CVD) apparatus wherein 101 stands for a layer-forming chamber, 102 stands for an exhaust unit, 103 stands for a gas inlet unit, 104 stands for an inductively coupled plasma generator, 105 stands for a substrate holder, 106 stands for a high-frequency power source, 107 stands for a matching circuit, 108 stands for a quartz aperture, 109 stands for a substrate and 110 stands for a controller.

Next, a layer-forming method with the use of the ICPCVD (inductively coupled plasma CVD) apparatus will be described.

The substrate 109 is put on the substrate holder 105.

The layer-forming chamber 101 is deaerated to about 0.0001 Pa with a vacuum pump in the exhaust unit 102.

A reaction gas is introduced from the gas inlet unit 103.

By controlling the matching circuit 107, a power of 13.56 MHz is applied from the high-frequency power source 106 to the inductively coupled plasma generator 104. The inductively coupled plasma generator 104 comprises a coil. Upon the application of the high-frequency power, electric wave is generated from the coil and transmitted via the quarts aperture 108 separating the plasma generator 104 from the layer-forming chamber 101.

Thus, plasma (the shaded part in the layer-forming chamber 101) generates at a position sufficiently apart from the substrate. Due to the magnetic field form the plasma generator 104, an inductive electrical field generates immediately below the quartz aperture 108. Thus, the kinetic energy of electrons is elevated by the electrical field and the ionization efficiency is increased, thereby generating uniform and high-density plasma at room temperature.

Reaction species in the plasma diffuse over the substrate 9 to thereby form a passivation layer.

The high-density plasma generates at room temperature. Compared with the existing plasma CVD method, a passivation layer having highly favorable qualities can be formed at room temperature. Owing to the operation at room temperature, the organic semiconductor is never deteriorated.

Since the plasma generates at a position sufficiently apart from the substrate, the substrate suffers from no plasma damage and, in its turn, the organic semiconductor is not deteriorated.

The composition of the layer-forming materials can be altered simply by changing the gas inlet amount and the gas type. Two or more materials can be continuously stacked in vacuo.

[Electron Cyclotron Resonance Plasma CVD]

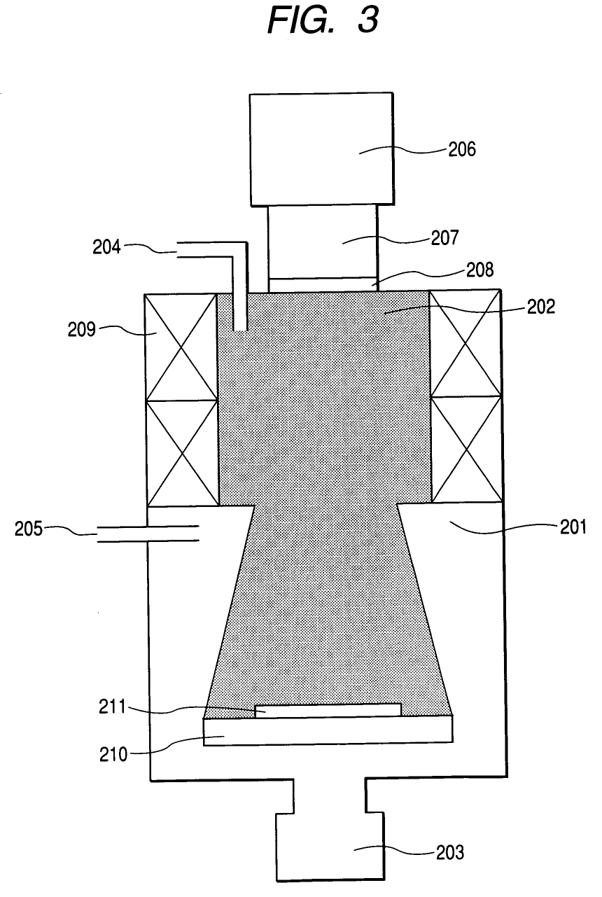

FIG. 3 shows an ECRCVD (electron cyclotron resonance plasma CVD) apparatus wherein 201 stands for a layer-forming chamber, 202 stands for a plasma-generating chamber, 203 stands for an exhaust unit, 204 and 205 stand for each a gas inlet unit, 206 stands for a microwave source, 207 stands for a microwave inlet pipe, 208 stands for a quartz aperture, 209 stands for an electric magnet, 210 stands for a substrate holder and 211 stands for a substrate.

Next, a layer-forming method with the use of the ECRCVD (electron cyclotron resonance plasma CVD) apparatus will be described.

The substrate 211 is put on the substrate holder 210.

The plasma-generating chamber 202 and the layer-forming chamber 201 are deaerated with a vacuum pump in the exhaust unit 203.

N₂, O₂, Ar or the like is introduced from the gas inlet unit 204.

Microwave (2.45 GHz) generated from the microwave source 206 is introduced into the plasma-generating chamber 202 via the microwave inlet pipe 207 and the quartz aperture 208. A magnetic field (87.5 mT) is applied to the electric magnet 209 and thus electron cyclotron resonance arises. As a result, the kinetic energy of electrons is elevated and the ionization efficiency is increased, thereby generating high-density plasma (the shaded part) at room temperature.

Electron cyclotron resonance condition: f_{c}=eB/2 πm Pc: resonance frequency (2.45 GHz), e: elementary charge, B: magnetic field (87.5 mT), m: electron mass.

The magnetic field is a divergent magnetic field which weakens as coming closer to the substrate holder 210, The high-density plasma in the plasma-generating chamber 202 migrates into the layer-forming chamber 201.

When SiH₄ is introduced from the gas inlet unit 205, it is decomposed by the plasma to form reaction species. Thus, a passivation layer grows on the substrate 211.

The high-density plasma generates at room temperature. Compared with the existing plasma CVD method, a passivation layer having highly favorable qualities can be formed at room temperature. Owing to the operation at room temperature, the organic semiconductor is never deteriorated.

Since the plasma generates at a position sufficiently apart from the substrate, the substrate suffers from no plasma damage and, in its turn, the organic semiconductor is not deteriorated.

### EXAMPLES

### Example 1

On a transparent counter electrode of a photoelectric conversion element with the use of an organic semiconductor, a silicon nitride layer was formed by using an ICPCVD apparatus (manufactured by SELVAC) under the following conditions.

SiH₄: 5 sccm

N₂: 95 sccm

Degree of vacuum at layer-formation: 0.1 Pa (before gas inlet: 0.001 Pa)

High frequency (rf) power: 500 W

Layer thickness: 0.5 μm.

Thus, the following results were obtained.

Visible light transmittance: not lower than 92%

Vapor permeability: not higher than 0.01 g m⁻² day⁻¹ atm⁻¹

Oxygen permeability: not higher than 0.01 g m⁻² day⁻¹ atm⁻¹

The layer-forming temperature did not exceed 70° C. The passivation layer suffered from no defect such as cracking. Since the passivation layer was formed on the photoelectric conversion element with the use of the organic semiconductor, the photoelectric characteristics were not deteriorated in the course of the passivation layer formation and the element showed a high temporal stability.

### Example 2

On a transparent counter electrode of a photoelectric conversion element with the use of an organic semiconductor, a passivation layer of the following composition was formed by using an ICPCVD apparatus.

SiNₓ 0.1 μm/SiOₓN_{y} 0.2 μm/SiNₓ 0.2 μm (First, a silicon nitride layer (0.1 μm) was formed followed by the formation of a silicon oxynitride layer (0.2 μm) and a silicon nitride layer (0.2 μn) in this order.)

Conditions for forming silicon nitride layer:

SiH₄: 5 sccm

N₂: 95 sccm

Degree of vacuum at layer-formation: 0.1 Pa (before gas inlet: 0.001 Pa)

High frequency (rf) power: 500 W

Conditions for forming silicon oxynitride layer:

SiH₄: 15 sccm

N₂: 285 sccm

O₂: 10 sccm

Degree of vacuum at layer-formation: 0.1 Pa (before gas inlet: 0.001 Pa)

High frequency (rf) power: 800 W

Thus, the following results were obtained.

Visible light transmittance: not lower than 92%

Vapor permeability: not higher than 0.01 g m⁻² day⁻¹ atm⁻¹

Oxygen permeability: not higher than 0.01 g m⁻²day⁻¹ atm⁻¹

The layer-forming temperature did not exceed 70° C. The passivation layer suffered from no defect such as cracking. Since the passivation layer was formed on the photoelectric conversion element with the use of the organic semiconductor, the photoelectric characteristics were not deteriorated in the course of the passivation layer formation and the element showed a high temporal stability.

### Comparative Example

On a transparent counter electrode of a photoelectric conversion element with the use of an organic semiconductor, a silicon oxide layer was formed by using a high-frequency magnetron sputtering apparatus (manufactured by SHIBAURA MECHATRONICS) under the following conditions.

Target SiO₂ Ar: 10 sccm

O₂: 10 sccm

Degree of vacuum at layer-formation: 0.1 Pa (before gas inlet: 0.001 Pa)

High frequency (rf) power: 400 W

Layer thickness: 0.5 μm.

Thus, the following results were obtained.

Visible light transmittance: higher than 98%

Vapor permeability: 1 g m⁻² day⁻¹ atm⁻¹

Oxygen permeability: 1 g m⁻² day⁻¹ atm⁻¹

The layer-forming temperature did not exceed 70° C. Since the passivation layer was formed on the photoelectric conversion element with the use of the organic semiconductor, the photoelectric characteristics were deteriorated and the element showed no temporal stability.

This application is based on Japanese Patent application JP 2005-54685, filed Feb. 28, 2005, the entire content of which is hereby incorporated by reference, the same as if set forth at length.

What is claimed is:

1. A photoelectric conversion element comprising:
a pixel electrode;
at least one photoelectric conversion layer containing an organic semiconductor;
a transparent counter electrode; and
a passivation layer containing an inorganic material, provided in this order.

2. The photoelectric conversion element as claimed in claim 1, wherein the inorganic material comprises at least one of a metal oxide and a metal nitride.

3. The photoelectric conversion element as claimed in claim 2, wherein the inorganic material comprises silicon oxide.

4. The photoelectric conversion element as claimed in claim 2, wherein the inorganic material comprises silicon nitride.

5. The photoelectric conversion element as claimed in claim 2, wherein the inorganic material comprises silicon oxynitride.

6. The photoelectric conversion element as claimed in claim 2, wherein the passivation layer has a stacked structure including two layers, one of the two layers containing one of two materials selected from silicon oxide, silicon nitride and silicon oxynitride, and the other of the two layers containing the other of the two materials.

7. The photoelectric conversion element as claimed in claim 1, wherein the passivation layer is formed in vacuo by a dry layer-formation method.

8. The photoelectric conversion element as claimed in claim 7, wherein the dry layer-formation method is a plasma-enhanced chemical vapor deposition method.

9. The photoelectric conversion element as claimed in claim 8, wherein the dry layer-formation method is an inductively coupled plasma CVD method.

10. The photoelectric conversion element as claimed in claim 8, wherein the dry layer-formation method is an electron cyclotron resonance plasma CVD method.

11. A method for producing a photoelectric conversion element including a pixel electrode, at least one photoelectric conversion layer containing an organic semiconductor, a transparent counter electrode, and a passivation layer containing an inorganic material, provided in this order,
wherein the method comprises: forming a passivation layer containing an inorganic material in vacuo by a dry layer-formation method on a transparent counter electrode.

12. The method as claimed in claim 11, wherein the dry layer-formation method is a plasma-enhanced chemical vapor deposition method.

13. The method as claimed in claim 12, wherein the dry layer-formation method is an inductively coupled plasma CVD method.

14. The method as claimed in claim 12, wherein the dry layer-formation method is an electron cyclotron resonance plasma CVD method.

15. A solid-state image pickup element comprising: an Si substrate including a CCD or CMOS signal transferring circuit; and the photoelectric conversion element as claimed in claim 1.
